(19) United States
(12) Patent Application Publication
(10) Pub. No.: US 2025/0346181 A1
(43) Pub. Date: Nov. 13, 2025

(54) APPARATUS AND METHOD FOR FORWARD COLLISION AVOIDANCE OF HOST VEHICLE

(71) Applicant: HL MANDO CORPORATION, Gyeonggi-do (KR)

(72) Inventor: Gyuwon KIM, Gyeonggi-do (KR)

(21) Appl. No.: 19/064,679

(22) Filed: Feb. 26, 2025

(30) Foreign Application Priority Data
May 9, 2024 (KR) 10-2024-0061249

(51) Int. Cl. B60Q 9/00; B60T 7/22; B60T 8/171; B60T 8/172; B60T 8/174; B60T 8/58; B60T 8/72; G06F 30/27

(52) U.S. Cl. CPC B60Q 9/008; B60T 7/22; B60T 8/171; B60T 8/172; B60T 8/174; B60T 8/58; B60T 8/72; G06F 30/27; B60T 2201/022; B60T 2210/12; B60T 2210/32; B60T 2220/02; B60T 2250/02; B60T 2250/04

(57) ABSTRACT

An apparatus for forward collision avoidance of a host vehicle includes a first sensor configured to detect a front of a vehicle; a second sensor configured to a speed of the host vehicle; and a controller that is communicatively connected to the first sensor and the second sensor and is configured to generate a collision warning based on a braking distance of the host vehicle and a braking tendency of a driver of the host vehicle.

### CROSS-REFERENCE TO RELATED APPLICATION

This application claims priority to and the benefit from Korean Patent Application No. 10-2024-0061249, filed on May 9, 2024, the disclosure of which is incorporated herein by reference in its entirety.

### BACKGROUND

The present disclosure relates to an apparatus and method for forward collision avoidance of a host vehicle, and more particularly, to an apparatus and method for forward collision avoidance of a host vehicle by calculating a braking distance by reflecting the vehicle condition and driving environment and considering the calculated braking distance and the driver's braking tendency.

Typically, the safe distance between a preceding vehicle and the host vehicle to prevent collision is determined based on the speed of each vehicle. When the host vehicle is moving at a low speed, a short braking distance is required, but when the host vehicle is moving at a high speed, a longer braking distance is required.

However, in situations where it is difficult to confirm the location of the preceding vehicle while driving the host vehicle, it is not easy for the driver to drive while maintaining this safe distance. That is, even if the brakes are suddenly applied just before a collision with the preceding vehicle, the collision cannot be avoided if the distance between the vehicles is not maintained at the braking distance.

Therefore, in order to prevent collisions and ensure safe driving of the host vehicle, it is essential to secure a safe distance to deal with unexpected situations of the preceding vehicle.

Recently, systems have been developed and installed in vehicles to prevent various safety accidents that may occur while driving. Existing technologies related to this include an apparatus for forward collision avoidance that warn of the risk of collision between the host vehicle and the preceding vehicle. These apparatuses for forward collision avoidance are designed to ensure the safety of vehicles and drivers, and use cameras, ultrasonic sensors, lasers, and radars to detect preceding vehicles that may cause a collision.

Conventional collision risk measurement methods judge collision risk based on uniformly set rules, such as the expected time to contact (TTC) between the host vehicle and the preceding vehicle and the expected distance to contact (DTC) between the host vehicle and the preceding vehicle, making it difficult to reflect various risk situations.

In addition, conventional collision risk measurement methods may cause drivers to become insensitive to the warning or feel uncomfortable because they warn drivers even when the drivers are aware of the collision risk.

### SUMMARY

The present disclosure is to solve the above problems, and is directed to providing an apparatus and method for forward collision avoidance of a host vehicle, capable of effectively preventing a collision accident by flexibly calculating the braking distance by reflecting the mass of the host vehicle and the friction coefficient of the road surface and performing collision warning and autonomous emergency braking.

In addition, the present disclosure is also directed to providing an apparatus and method for forward collision avoidance of a host vehicle, capable of solving the problem of causing inconvenience to the driver by generating an unnecessary collision warning even when the driver is well aware of the current driving situation of the host vehicle according to the driver's braking tendency.

The problems of the present disclosure are not limited to those mentioned above, and other problems not mentioned will be clearly understood by those of ordinary skill in the art from the following description.

In order to solve the above-mentioned problems, the present disclosure provides an apparatus for forward collision avoidance of a host vehicle, the apparatus including a first sensor configured to detect a front of a vehicle; a second sensor configured to a speed of the host vehicle; and a controller that is communicatively connected to the first sensor and the second sensor and is configured to generate a collision warning based on a braking distance of the host vehicle and a braking tendency of a driver of the host vehicle.

Here, the controller may calculate the braking distance of the host vehicle based on the mass of the host vehicle and a friction coefficient of a road surface on which the host vehicle is driving.

In addition, the controller may calculate the braking distance of the host vehicle based on the presence of a preceding vehicle in front of the host vehicle.

In addition, the controller may calculate the braking distance based on the fact that the relative speed of the host vehicle with respect to the preceding vehicle is greater than or equal to a reference speed and the driver has not braked.

In addition, the controller may brake the host vehicle based on a vehicle-to-vehicle distance between the host vehicle and a preceding vehicle in front of the host vehicle being less than or equal to the braking distance.

In addition, the apparatus for forward collision avoidance of a host vehicle of the present disclosure may further include a memory storing an artificial neural network model that has learned the braking tendency of the driver.

Here, the artificial neural network model may be generated by learning whether the driver's braking exists according to a speed of the host vehicle, a vehicle-to-vehicle distance between the host vehicle and a preceding vehicle in front of the host vehicle, and a relative speed of the host vehicle with respect to the preceding vehicle.

In addition, the controller may determine whether the host vehicle needs to be braked by inputting a speed of the host vehicle, a vehicle-to-vehicle distance between the host vehicle and a preceding vehicle in front of the host vehicle, and a relative speed of the host vehicle with respect to the preceding vehicle to the artificial neural network model.

Specifically, the artificial neural network model may determine that the braking of the host vehicle is necessary based on the fact that the driver had braked at: the speed of the vehicle, the vehicle-to-vehicle distance between the vehicle and the preceding vehicle in front of the host vehicle, and the relative speed of the host vehicle with respect to the preceding vehicle.

In addition, the artificial neural network model may determine that the braking of the host vehicle is unnecessary based on the fact that the driver had not braked at: the speed of the vehicle, the vehicle-to-vehicle distance between the host vehicle and the preceding vehicle in front of the host vehicle, and the relative speed of the host vehicle with respect to the preceding vehicle.

In addition, the controller may generate a collision warning on the basis that the vehicle-to-vehicle distance exceeds the braking distance and the host vehicle needs to be braked.

In addition, the artificial neural network model may be updated every predetermined period.

In addition, the memory may store a plurality of the artificial neural network models that have learned braking tendencies of a plurality of drivers of the host vehicle, respectively.

In addition, the controller may determine, based on the driver selecting one of the plurality of artificial neural network models, whether the host vehicle needs braking using the selected artificial neural network model.

In addition, the controller may be connected to the first sensor and the second sensor through CAN (Controller Area Network) communication of the host vehicle.

In addition, the present disclosure provides a method for forward collision avoidance of a host vehicle using a controller, the method including generating an artificial neural network model that has learned a braking tendency of a driver of the host vehicle; calculating a braking distance of the host vehicle based on the fact that a relative speed of the host vehicle with respect to a preceding vehicle is greater than or equal to a reference speed and the driver has not braked; determining whether the host vehicle needs to be braked by inputting a speed of the host vehicle, a vehicle-to-vehicle distance between the host vehicle and a preceding vehicle in front of the host vehicle, and a relative speed of the host vehicle with respect to the preceding vehicle to the artificial neural network model; and generating a collision warning on the basis that the vehicle-to-vehicle distance exceeds the braking distance and the host vehicle needs to be braked.

Here, the generating an artificial neural network model may be a step of generating an artificial neural network model by learning whether the driver's braking exists according to a speed of the host vehicle, a vehicle-to-vehicle distance between the host vehicle and a preceding vehicle in front of the host vehicle, and a relative speed of the host vehicle with respect to the preceding vehicle.

In addition, the determining whether the host vehicle needs to be braked may be a step of determining whether the host vehicle needs to be braked by inputting a speed of the host vehicle, a vehicle-to-vehicle distance between the host vehicle and a preceding vehicle in front of the host vehicle, and a relative speed of the host vehicle with respect to the preceding vehicle to the artificial neural network model.

In addition, the determining whether the host vehicle needs to be braked may be a step of determining that the braking of the host vehicle is necessary based on the fact that the driver had braked at: the speed of the vehicle, the vehicle-to-vehicle distance between the vehicle and the preceding vehicle in front of the host vehicle, and the relative speed of the host vehicle with respect to the preceding vehicle.

In addition, the determining whether the host vehicle needs to be braked may be a step of determining that the braking of the host vehicle is unnecessary based on the fact that the driver had not braked at: the speed of the vehicle, the vehicle-to-vehicle distance between the host vehicle and the preceding vehicle in front of the host vehicle, and the relative speed of the host vehicle with respect to the preceding vehicle.

According to the present disclosure, it is possible to effectively prevent a collision accident by flexibly calculating the braking distance by reflecting the mass of the host vehicle and the friction coefficient of the road surface and performing collision warning and autonomous emergency braking.

In addition, according to the present disclosure, it is possible to solve the problem of causing inconvenience to the driver by generating an unnecessary collision warning even when the driver is well aware of the current driving situation of the host vehicle according to the driver's braking tendency.

Advantageous effects of the present disclosure are not limited to the above-described effects, and should be understood to include all effects that can be inferred from the configuration of the disclosure described in the detailed description or claims of the present disclosure.

### BRIEF DESCRIPTION OF THE DRAWINGS

The above and other objects, features and advantages of the present disclosure will become more apparent to those of ordinary skill in the art by describing exemplary embodiments thereof in detail with reference to the accompanying drawings, in which:

FIG. 1 is a block diagram of an apparatus for forward collision avoidance of a host vehicle according to an exemplary embodiment of the present disclosure;

FIG. 2 is a drawing for explaining a forward collision avoidance operation based on the braking distance of a host vehicle in an apparatus for forward collision avoidance of a host vehicle according to an exemplary embodiment of the present disclosure;

FIG. 3 is a drawing for explaining a forward collision avoidance operation based on the braking distance of a host vehicle and the braking tendency of a driver of the host vehicle in an apparatus for forward collision avoidance of a host vehicle according to an exemplary embodiment of the present disclosure;

FIGS. 4 to 6 are graphs exemplarily showing the braking tendencies of drivers of host vehicles; and

FIG. 7 is a flow chart of a method for forward collision avoidance of a host vehicle according to an exemplary embodiment of the present disclosure.

### DETAILED DESCRIPTION

Hereinafter, embodiments of the present disclosure will be described in detail so that those skilled in the art to which the present disclosure pertains can easily carry out the embodiments. The present disclosure may be implemented in many different forms and is not limited to the embodiments described herein. In order to clearly describe the present disclosure, portions not related to the description are omitted from the accompanying drawings, and the same or similar components are denoted by the same reference numerals throughout the specification.

The words and terms used in the specification and the claims are not limitedly construed as their ordinary or dictionary meanings, and should be construed as meaning and concept consistent with the technical spirit of the present disclosure in accordance with the principle that the inventors can define terms and concepts in order to best describe their disclosure.

In the specification, it should be understood that the terms such as “comprise” or “have” are intended to specify the presence of features, numbers, steps, operations, components, parts, or combinations thereof described in the specification and do not preclude the possibility of the presence or addition of one or more other features, numbers, steps, operations, components, parts, or combinations thereof.

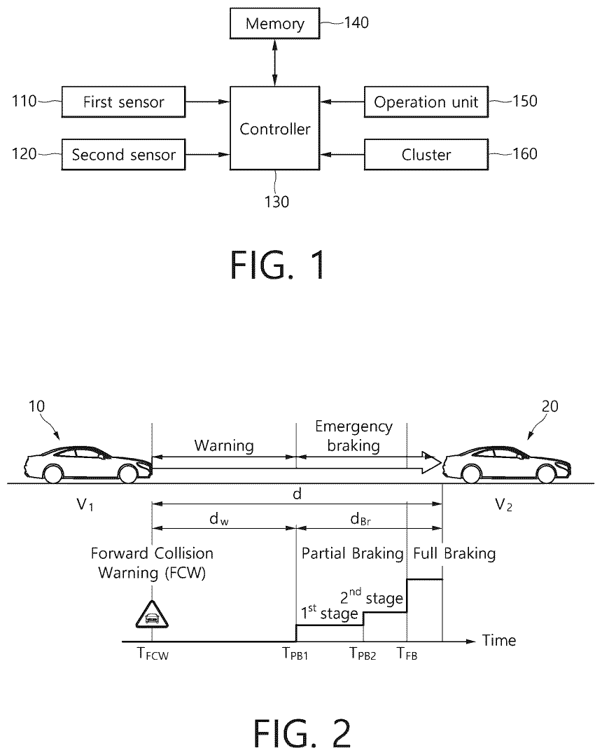

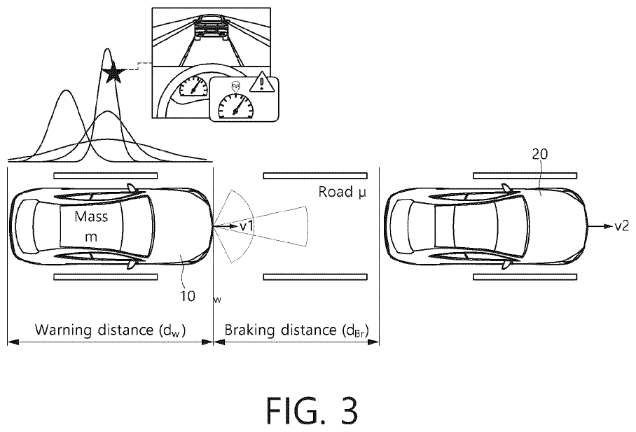

FIG. 1 is a block diagram of an apparatus for forward collision avoidance of a host vehicle according to an exemplary embodiment of the present disclosure, FIG. 2 is a drawing for explaining a forward collision avoidance operation based on the braking distance of a host vehicle in an apparatus for forward collision avoidance of a host vehicle according to an exemplary embodiment of the present disclosure, and FIG. 3 is a drawing for explaining a forward collision avoidance operation based on the braking distance of a host vehicle and the braking tendency of a driver of the host vehicle in an apparatus for forward collision avoidance of a host vehicle according to an exemplary embodiment of the present disclosure.

An apparatus for forward collision avoidance (FCA) of a host vehicle according to an exemplary embodiment of the present disclosure may perform a forward collision warning (FCW) function and an autonomous emergency braking (AEB) function.

To this end, the apparatus for forward collision avoidance of a host vehicle according to an exemplary embodiment of the present disclosure receives sensing data from a sensor (e.g., camera, radar, lidar, etc.) mounted on the host vehicle 10 and acquires information such as the presence or absence of the preceding vehicle 20 traveling on the same lane as the host vehicle 10, the vehicle-to-vehicle distance between the host vehicle 10 and the preceding vehicle 20, and the relative speed and relative deceleration of the host vehicle 10 for the preceding vehicle 20, and controls the braking device by generating a collision warning or performing cooperative control with a braking control device using the acquired information.

In autonomous emergency braking, the braking control device calculates and distributes the braking torque required for braking, while controlling the braking force of the host vehicle through hydraulic control of the braking device.

As shown in FIG. 1, the apparatus for forward collision avoidance of a host vehicle according to an exemplary embodiment of the present disclosure may include a first sensor 110, a second sensor 120, controller 130, memory 140, an operation unit 150, and a cluster 160.

The first sensor 110 may detect the front of the host vehicle 10, for example, the preceding vehicle 20. Here, the first sensor 110 may be a radar, a lidar, a camera, and an ultrasonic sensor, but is not limited thereto.

The second sensor 120 may detect the speed of the host vehicle 10. Here, the second sensor 120 may be a speed sensor.

The controller 130 is communicatively connected to the first sensor 110 and the second sensor 120, may generate a collision warning based on the braking distance of the host vehicle 10 and the braking tendency of the driver of the host vehicle 10, and may brake the host vehicle 10.

Here, the controller 130 may be connected to the first sensor 110 and the second sensor 120 through CAN (Controller Area Network) communication of the host vehicle 10. That is, the controller 130 may receive sensing data from the first sensor 110 and the second sensor 120 through CAN communication.

Referring to FIGS. 2 and 3, the apparatus for forward collision avoidance of a host vehicle according to an exemplary embodiment of the present disclosure may calculate a vehicle-to-vehicle distance d between the host vehicle 10 and the preceding vehicle 20 when the preceding vehicle 20 exists in front of the host vehicle 10, and may calculate a braking distance d_{Br} at which the host vehicle 10 can avoid collision with the preceding vehicle 20 when braking the host vehicle 10.

Here, the apparatus for forward collision avoidance of a host vehicle according to an exemplary embodiment of the present disclosure may perform a forward collision warning (FCW) function when the vehicle-to-vehicle distance d between the host vehicle 10 and the preceding vehicle 20 is within a reference distance d_{w}+d_{Br}.

In addition, the apparatus for forward collision avoidance of a host vehicle according to an exemplary embodiment of the present disclosure may perform an autonomous emergency braking (AEB) function when the vehicle-to-vehicle distance d between the host vehicle 10 and the preceding vehicle 20 is within the braking distance d_{Br}.

That is, the apparatus for forward collision avoidance of a host vehicle according to an exemplary embodiment of the present disclosure may generate a collision warning from a time point T_{FCW} when the vehicle-to-vehicle distance d between the host vehicle 10 and the preceding vehicle 20 is the reference distance d_{w}+d_{Br} to a time point T_{PB1} when the vehicle-to-vehicle distance d is the braking distance d_{Br}, and may emergency brake the host vehicle 10 from a time point T_{PB1} when the vehicle-to-vehicle distance d between the host vehicle 10 and the preceding vehicle 20 is the braking distance d_{Br} until the host vehicle 10 collides with the preceding vehicle 20.

In this case, the autonomous emergency braking may be performed by increasing the braking force step by step. For example, as shown in FIG. 2, the apparatus for forward collision avoidance of a host vehicle according to an exemplary embodiment of the present disclosure may perform partial braking of a first stage with a first braking force from T_{PB1} to T_{PB2}, perform partial braking of a second stage with a second braking force greater than the first braking force from T_{PB2} to TFB, and perform full braking with the maximum braking force that the braking device can apply after TFB.

Meanwhile, general forward collision avoidance technology is a rule-based logic that performs collision warnings based on safety index (SI), for example, expected time to collision (TTC). That is, it performs a collision warning when the expected time to collision is less than a first threshold value (e.g., 2 seconds), and performs forced braking when the expected time to collision is less than a second threshold value (e.g., 1 second) which is less than the first threshold value.

Here, the expected time to collision (TTC) may be calculated by Equation 1 below.

$$TTC = \frac{d}{{v}_{1} - {v}_{2}} \qquad [ Equation 1 ]$$

Where, v₁ denotes the speed of the host vehicle 10, v₂ denotes the speed of the preceding vehicle 20, and d denotes the vehicle-to-vehicle distance between the host vehicle 10 and the counterpart vehicle 20.

However, since this expected time to collision (TTC)-based forward collision avoidance technology does not take into account braking distances that reflect vehicle conditions and driving environments, there is a problem that braking by collision warnings during high-speed driving does not completely prevent collisions.

In addition, there is a problem of generating an unnecessary collision warning because it does not reflect the driver's braking tendency.

In order to solve these problems, the apparatus for forward collision avoidance of a host vehicle according to an exemplary embodiment of the present disclosure calculates a braking distance by reflecting the vehicle condition (e.g., the mass of the host vehicle 10) and the driving environment (e.g., the friction coefficient of the road surface), and provides an apparatus for forward collision avoidance of a host vehicle 10 that reflects the calculated braking distance and the driver's braking tendency.

Specifically, the controller 130 may calculate the braking distance of the host vehicle 10 based on the mass m of the host vehicle 10 and the friction coefficient μ of the road surface on which the host vehicle 10 travels.

The braking distance d_{Br} of the host vehicle 10 may be calculated by Equation 2 below.

$${d}_{Br} = \frac{{γ}_{m} m}{ρ {C}_{d} {A}_{f}} ln ( 1 + \frac{ρ {C}_{d} {A}_{f} {v}_{1}^{2}}{2 ( {η}_{b} μ mg + {f}_{r} mg )} ) \qquad [ Equation 2 ]$$

Where, γₘ denotes the mass factor, m denotes the mass of the host vehicle 10, ρ denotes the air density in front of the host vehicle 10, C_{d} denotes the air resistance coefficient, A_{f} denotes the front area of the host vehicle 10, v₁ denotes the speed of the host vehicle 10, η_{b} denotes the brake efficiency of the host vehicle 10, μ denotes the friction coefficient of the road surface, g denotes the gravitational acceleration, and fᵣ denotes the rolling resistance constant.

As shown in Equation 2, the braking distance d_{Br} of the host vehicle 10 is proportional to the mass m of the host vehicle 10 and inversely proportional to the friction coefficient μ of the road surface. That is, the braking distance d_{Br} of the host vehicle 10 increases as the mass m of the host vehicle 10 increases, and decreases as the friction coefficient μ of the road surface increases.

Here, the mass m of the host vehicle 10 varies depending on the number of passengers of the host vehicle 10 and the mass of the objects mounted on the host vehicle 10 and may be sensed through a sensor installed inside the host vehicle 10.

In addition, the friction coefficient μ of the road surface varies depending on the degree to which the tire slides against the road surface while driving the host vehicle 10, and may be sensed through a sensor mounted on the tire.

As such, the apparatus for forward collision avoidance of a host vehicle according to an exemplary embodiment of the present disclosure can effectively prevent a collision accident by flexibly calculating the braking distance d_{Br} by reflecting the mass m of the host vehicle 10 and the friction coefficient μ of the road surface and performing collision warning and autonomous emergency braking.

The controller 130 may calculate the braking distance d_{Br} of the host vehicle 10 based on the presence of the preceding vehicle 20 in front of the host vehicle 10. That is, the controller 130 may minimize the computational load by calculating the braking distance only when the preceding vehicle 20 is present, rather than continuously calculating the braking distance.

In addition, the controller 130 may calculate the braking distance based on the relative speed of the host vehicle 10 with respect to the preceding vehicle 20 being greater than or equal to the reference speed (e.g., 1 m/s) and not braking by the driver. Here, the meaning that the relative speed is greater than or equal to the reference speed means that the vehicle-to-vehicle distance between the host vehicle 10 and the counterpart vehicle 20 is gradually decreasing. Accordingly, in this case, the controller 130 prepares to perform a collision warning or autonomous emergency braking by calculating a braking distance.

The controller 130 may brake the host vehicle 10 on the basis that the vehicle-to-vehicle distance d between the host vehicle 10 and the preceding vehicle 20 in front of the host vehicle 10 is less than or equal to the braking distance d_{Br}. In this case, autonomous emergency braking may be performed together with the collision warning or autonomous emergency braking may be performed after the collision warning.

Here, the braking distance d_{Br} reflects the mass m of the host vehicle 10 and the friction coefficient μ of the road surface as described above, and as the mass m of the host vehicle 10 increases, the braking distance d_{Br} increases, and as the friction coefficient μ of the road surface increases, the braking distance d_{Br} decreases.

In addition, the braking distance d_{Br} may be a distance at which collision of the preceding vehicle 20 may be avoided by maximum braking force of the braking device.

The apparatus for forward collision avoidance of a host vehicle according to an exemplary embodiment of the present disclosure may perform a collision warning by reflecting the braking tendency of the driver of the host vehicle 10.

To this end, the apparatus for forward collision avoidance of a host vehicle according to an exemplary embodiment of the present disclosure performs a collision warning using an artificial neural network model that has learned the driver's braking tendency.

Such an artificial neural network model may be stored in the memory 140, and the controller 130 performs a collision warning using the artificial neural network model stored in the memory 140.

The memory 140 may include a hardware device configured to store and perform an artificial neural network model. For example, the memory 140 may include a storage medium such as a ROM, a RAM, and a flash memory. In addition, the memory 140 may include a magnetic medium such as a floppy disk and a magnetic tape; an optical medium such as a compact disk read only memory (CD-ROM) and a digital video disk (DVD); a magneto-optical medium such as a floptical disk, a read-only memory; and the like.

The artificial neural network model may be generated by learning whether the driver's braking exists according to the speed of the host vehicle 10, the vehicle-to-vehicle distance between the host vehicle 10 and the preceding vehicle 20 in front of the host vehicle 10, and the relative speed of the host vehicle 10 with respect to the preceding vehicle 20, based on training data, which is the driver's past driving data.

The artificial neural network model may be the Gaussian Mixture Model (GMM) to which the unsupervised learning method is applied, the K-Nearest Neighbor (KNN) to which the semi-supervised learning method is applied, and the eXtreme Gradient Boosting (XGB) to which the supervised learning method is applied.

Here, the unsupervised learning method has no label information in the training data, the semi-supervised learning method has only label information for non-braking situations among the training data, and the supervised learning method has label information for all training data, i.e., non-braking situations and 2 seconds before braking.

The F1 score is high in the order of supervised learning method, semi-supervised learning method, and unsupervised learning method, but in the case of supervised learning method, since training data is insufficient and non-uniform, it is preferable that the artificial neural network model according to an exemplary embodiment of the present disclosure is generated by learning a semi-supervised learning method.

Here, the F1 score is a geometric mean value of degree of precision and recall factor as a classification performance indicator.

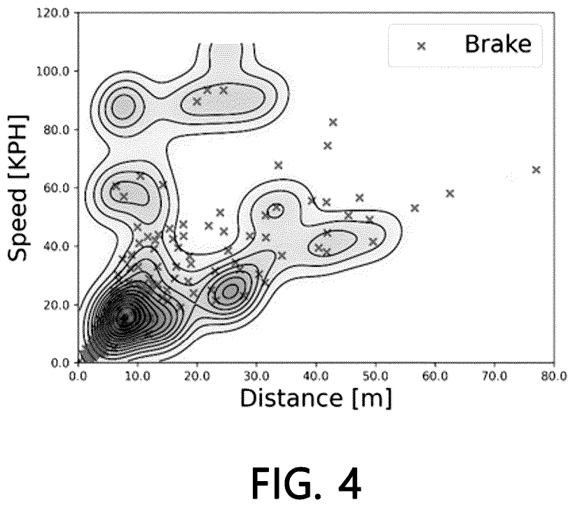

FIGS. 4 to 6 are graphs exemplarily showing the braking tendencies of drivers of host vehicles. In FIGS. 4 to 6, the non-braking situation is indicated by contour lines, and the braking situation is indicated by x.

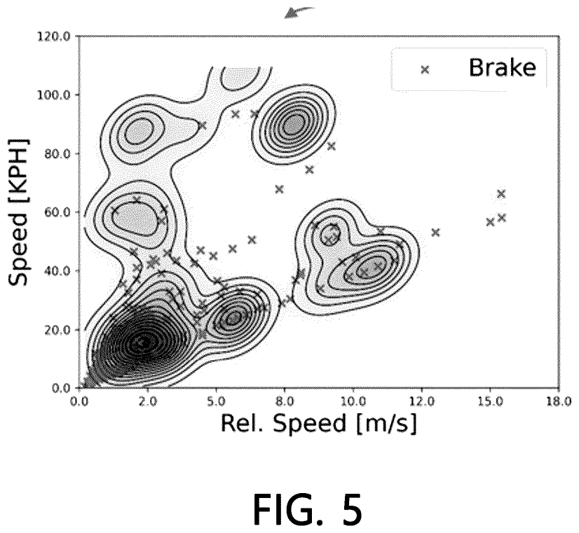

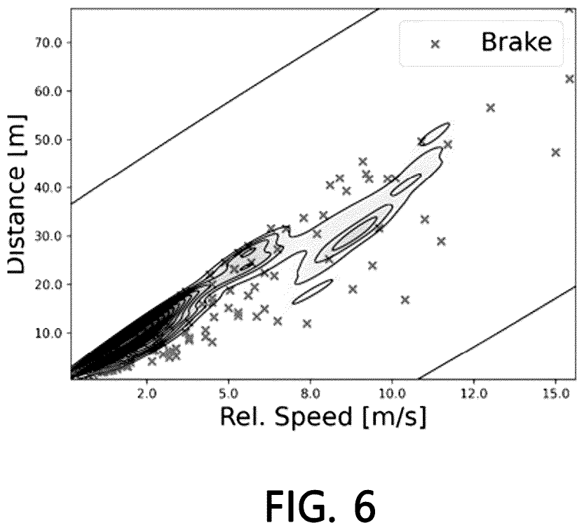

FIG. 4 shows the driver's braking situation and non-braking situation according to the vehicle-to-vehicle distance between the host vehicle 10 and the counterpart vehicle 20 and the speed of the host vehicle 10, FIG. 5 shows the driver's braking situation and non-braking situation according to the relative speed (Rel. Speed) of own vehicle 10 and the speed (Speed) of host vehicle 10 with respect to the counterpart vehicle 20, and FIG. 6 shows the driver's braking situation and non-braking situation according to the relative speed (Rel. Speed) of the host vehicle 10 with respect to the counterpart vehicle 20 and the vehicle-to-vehicle distance (Distance) between the host vehicle 10 and the counterpart vehicle 20.

The controller 130 may input the speed of the host vehicle 10, the vehicle-to-vehicle distance between the host vehicle 10 and the preceding vehicle 20 in front of the host vehicle 10, and the relative speed of the host vehicle 10 with respect to the preceding vehicle 20 to the artificial neural network model to determine whether the host vehicle 10 needs to be braked.

Specifically, the artificial neural network model can determine that the braking of the host vehicle 10 is necessary based on the fact that the driver had braked at: the speed of the vehicle 10, the vehicle-to-vehicle distance between the host vehicle 10 and the preceding vehicle 20 in front of the host vehicle 10, and the relative speed of the host vehicle 10 with respect to the preceding vehicle 20.

For example, referring to FIG. 4, if the training data, which is the driver's past driving data, contains information on the braking situation label that the driver had braked under the condition that the speed of the host vehicle 10 is 80 KPH and the vehicle-to-vehicle distance between the host vehicle 10 and the preceding vehicle 20 is 5 m, the artificial neural network model may determine that the host vehicle 10 needs to be braked when the sensing data of the same conditions are input from the first sensor 110 and the second sensor 120.

In addition, referring to FIG. 5, if the training data, which is the driver's past driving data, contains information on the braking situation label that the driver had braked under the condition that the speed of the host vehicle 10 is 80 KPH and the relative speed of the host vehicle 10 with respect to the preceding vehicle 20 is 5 m/s, the artificial neural network model may determine that the host vehicle 10 needs to be braked when the sensing data of the same conditions are input from the first sensor 110 and the second sensor 120.

In addition, referring to FIG. 6, if the training data, which is the driver's past driving data, contains information on the braking situation label that the driver had braked under the condition that the relative speed of the host vehicle 10 with respect to the preceding vehicle 20 is 5 m/s and the vehicle-to-vehicle distance between the host vehicle 10 and the counterpart vehicle 20 is 5 m, the artificial neural network model may determine that the host vehicle 10 needs to be braked when the sensing data of the same conditions are input from the first sensor 110 and the second sensor 120.

In addition, the artificial neural network model can determine that the braking of the host vehicle 10 is unnecessary based on the fact that the driver had not braked at: the speed of the vehicle 10, the vehicle-to-vehicle distance between the host vehicle 10 and the preceding vehicle 20 in front of the host vehicle 10, and the relative speed of the host vehicle 10 with respect to the preceding vehicle 20.

For example, referring to FIG. 4, if the training data, which is the driver's past driving data, contains information on the non-braking situation label that the driver had not braked under the condition that the speed of the host vehicle 10 is 60 KPH and the vehicle-to-vehicle distance between the host vehicle 10 and the preceding vehicle 20 is 5 m, the artificial neural network model may determine that the host vehicle 10 does not need to be braked when the sensing data of the same conditions are input from the first sensor 110 and the second sensor 120.

In addition, referring to FIG. 5, if the training data, which is the driver's past driving data, contains information on the non-braking situation label that the driver had not braked under the condition that the speed of the host vehicle 10 is 80 KPH and the relative speed of the host vehicle 10 with respect to the preceding vehicle 20 is 1 m/s, the artificial neural network model may determine that the host vehicle 10 does not need to be braked when the sensing data of the same conditions are input from the first sensor 110 and the second sensor 120.

In addition, referring to FIG. 6, if the training data, which is the driver's past driving data, contains information on the non-braking situation label that the driver had not braked under the condition that the relative speed of the host vehicle 10 with respect to the preceding vehicle 20 is 5 m/s and the vehicle-to-vehicle distance between the host vehicle 10 and the counterpart vehicle 20 is 10 m, the artificial neural network model may determine that the host vehicle 10 does not need to be braked when the sensing data of the same conditions are input from the first sensor 110 and the second sensor 120.

As such, the apparatus for forward collision avoidance of a host vehicle according to an exemplary embodiment of the present disclosure does not uniformly determine the braking necessity of the host vehicle 10 according to the vehicle-to-vehicle distance or the expected time to collision, but flexibly determines the braking necessity of the host vehicle 10 by reflecting the driver's braking tendency. That is, even under the same driving conditions, it may determine that driver A needs braking while driver B does not need braking according to the braking tendencies of the drivers.

Accordingly, the apparatus for forward collision avoidance of a host vehicle according to an exemplary embodiment of the present disclosure can solve the problem of causing inconvenience to the driver by generating an unnecessary collision warning even when the driver is well aware of the current driving situation of the host vehicle 10 according to the driver's braking tendency.

The controller 130 may generate a collision warning based on the vehicle-to-vehicle distance d exceeds the braking distance d_{Br} and the braking of the host vehicle 10 is necessary. Here, the fact that the vehicle-to-vehicle distance d exceeds the braking distance d_{Br} means that the braking force of the braking device of the host vehicle 10 may sufficiently avoid the forward collision at this point in time, and thus a collision warning is generated in advance to prevent the collision.

The controller 130 may warn the driver of the risk of collision with a vehicle in front through the cluster 160 using a video warning, an audio warning, a haptic warning, and the like.

Meanwhile, the braking tendency of the driver of the host vehicle 10 may be varied. As such, when the driver's braking tendency changes, there is a high risk of misjudgment when determining the braking necessity using an artificial neural network model that has learned the driver's braking tendency before the change.

Accordingly, it is preferable that the artificial neural network model according to an exemplary embodiment of the present disclosure is updated every predetermined period. That is, the artificial neural network model may be updated by re-learning the driver's braking tendency collected in the most recent predetermined period range.

In addition, there may be several drivers driving the host vehicle 10. In this case, using an artificial neural network model that has learned one driver's braking tendency, determining the necessity of braking while other drivers are driving the host vehicle is highly likely to be misjudgmented, which poses a risk of collision and may provide inconvenience to other drivers.

Accordingly, the apparatus for forward collision avoidance of a host vehicle according to an exemplary embodiment of the present disclosure may generate a collision warning based on braking tendencies of a plurality of drivers, respectively.

To this end, the memory 140 may store a plurality of artificial neural network models that have learned braking tendencies of a plurality of drivers of the host vehicle 10, respectively.

Using the operation unit 150, the driver may select an artificial neural network model that has learned the driver's braking tendency.

Accordingly, the controller 130 may determine whether the host vehicle 10 needs braking using the selected artificial neural network model based on the driver selecting one of a plurality of artificial neural network models.

As such, the apparatus for forward collision avoidance of a host vehicle according to an exemplary embodiment of the present disclosure can effectively prevent a collision accident by flexibly calculating the braking distance d_{Br} by reflecting the mass m of the host vehicle 10 and the friction coefficient μ of the road surface and performing collision warning and autonomous emergency braking.

In addition, the apparatus for forward collision avoidance of a host vehicle according to an exemplary embodiment of the present disclosure can solve the problem of causing inconvenience to the driver by generating an unnecessary collision warning even when the driver is well aware of the current driving situation of the host vehicle 10 according to the driver's braking tendency.

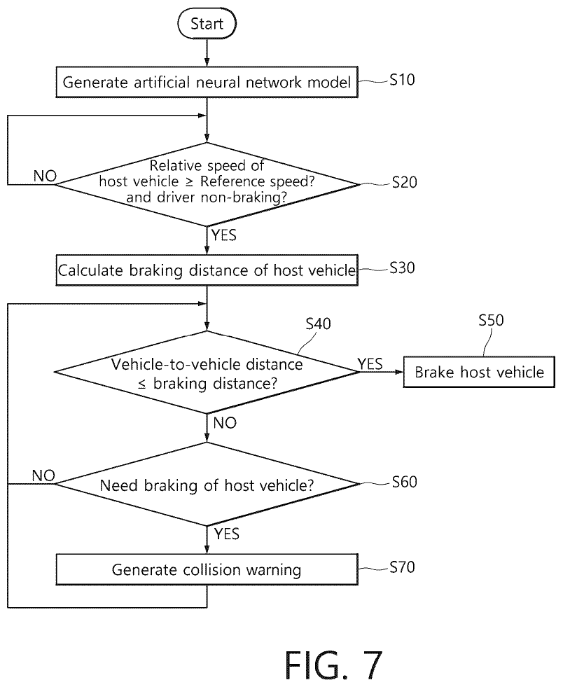

FIG. 7 is a flow chart of a method for forward collision avoidance of a host vehicle according to an exemplary embodiment of the present disclosure.

Hereinafter, a method for forward collision avoidance of a host vehicle according to an exemplary embodiment of the present disclosure will be described with reference to FIG. 7, but the same contents as those described above will be omitted.

The method for forward collision avoidance of a host vehicle according to an exemplary embodiment of the present disclosure is a method for warning a forward collision of a host vehicle 10 using controller 130, and first, an artificial neural network model that has learned the braking tendency of the driver of the host vehicle 10 is generated (S10).

Here, the artificial neural network model may be generated by learning whether the driver's braking exists according to the speed of the host vehicle 10, the vehicle-to-vehicle distance between the host vehicle 10 and the preceding vehicle 20 in front of the host vehicle 10, and the relative speed of the host vehicle 10 with respect to the preceding vehicle 20.

Next, it is determined whether the relative speed of the host vehicle 10 with respect to the preceding vehicle 20 is greater than or equal to the reference speed (e.g., 1 m/s), and it is determined whether it is a non-braking situation in which the driver has not braked (S20).

In this case, the braking distance of the host vehicle 10 is calculated based on the fact that the relative speed of the host vehicle 10 with respect to the preceding vehicle 20 is greater than or equal to the reference speed and the driver did not brake (S30).

Next, it is determined whether the vehicle-to-vehicle distance between the host vehicle 10 and the counterpart vehicle 20 is less than or equal to the braking distance (S40).

In this case, if the vehicle-to-vehicle distance between the host vehicle 10 and the counterpart vehicle 20 is less than or equal to the braking distance, the host vehicle 10 is emergency-braked (S50).

In contrast, if the vehicle-to-vehicle distance between the host vehicle 10 and the counterpart vehicle 20 is greater than the braking distance, the speed of the host vehicle 10, the vehicle-to-vehicle distance between the host vehicle 10 and the preceding vehicle 20 in front of the host vehicle 10, and the relative speed of the host vehicle 10 with respect to the preceding vehicle 20 are input to the artificial neural network model to determine whether the host vehicle 10 needs to be braked (S60).

Here, it is determined that the braking of the host vehicle 10 is necessary based on the fact that the driver had braked at: the speed of the vehicle 10, the vehicle-to-vehicle distance between the host vehicle 10 and the preceding vehicle 20 in front of the host vehicle 10, and the relative speed of the host vehicle 10 with respect to the preceding vehicle 20.

In contrast, it is determined that the braking of the host vehicle 10 is unnecessary based on the fact that the driver had not braked at: the speed of the vehicle 10, the vehicle-to-vehicle distance between the host vehicle 10 and the preceding vehicle 20 in front of the host vehicle 10, and the relative speed of the host vehicle 10 with respect to the preceding vehicle 20.

In this case, a collision warning is generated on the basis that the vehicle-to-vehicle distance between the host vehicle 10 and the counterpart vehicle 20 exceeds the braking distance and the host vehicle 10 needs to be braked (S70).

Next, it is determined again whether the vehicle-to-vehicle distance between the host vehicle 10 and the counterpart vehicle 20 is less than or equal to the braking distance (S40), and if the vehicle-to-vehicle distance between the host vehicle 10 and the counterpart vehicle 20 is less than or equal to the braking distance, the host vehicle 10 is emergency-braked (S50). That is, autonomous emergency braking is performed if the vehicle-to-vehicle distance between the host vehicle 10 and the counterpart vehicle 20 is less than or equal to the braking distance because the driver does not brake despite the collision warning.

In contrast, if braking of the host vehicle 10 is unnecessary, it is determined again whether the vehicle-to-vehicle distance between the host vehicle 10 and the counterpart vehicle 20 is less than or equal to the braking distance (S40).

As such, the method for forward collision avoidance of a host vehicle according to an exemplary embodiment of the present disclosure can effectively prevent a collision accident by flexibly calculating the braking distance d_{Br} by reflecting the mass m of the host vehicle 10 and the friction coefficient μ of the road surface and performing collision warning and autonomous emergency braking.

In addition, the method for forward collision avoidance of a host vehicle according to an exemplary embodiment of the present disclosure can solve the problem of causing inconvenience to the driver by generating an unnecessary collision warning even when the driver is well aware of the current driving situation of the host vehicle 10 according to the driver's braking tendency.

Meanwhile, the present disclosure additionally provides a non-transitory computer-readable storage medium having stored thereon a program for performing the method for forward collision avoidance of a host vehicle. Specifically, the present disclosure may provide a non-transitory computer-readable storage medium having stored thereon a program including at least one instruction for performing the method for forward collision avoidance of a host vehicle.

In this case, the instruction may include a machine language code generated by a compiler. In addition, the instruction may include advanced language code executable by a computer.

The storage medium may include a hardware device configured to store and perform program instructions such as a hard disk, a magnetic medium such as a floppy disk and a magnetic tape, an optical medium such as a compact disk read only memory (CD-ROM) and a digital video disk (DVD), a magneto-optical medium such as a floptical disk, a read-only memory (ROM), a random access memory (RAM), a flash memory, and the like.

It should be understood that the effects of the present disclosure are not limited to the above-described effects, and include all effects inferable from a configuration of the disclosure described in detailed descriptions or claims of the present disclosure.

Although embodiments of the present disclosure have been described, the spirit of the present disclosure is not limited by the embodiments presented in the specification. Those skilled in the art who understand the spirit of the present disclosure will be able to easily suggest other embodiments by adding, changing, deleting, or adding components within the scope of the same spirit, but this will also be included within the scope of the spirit of the present disclosure.

What is claimed is:

1. An apparatus for collision avoidance of a host vehicle, the apparatus comprising:
a first sensor configured to detect one or more objects in front of the host vehicle;
a second sensor configured to detect a speed of the host vehicle; and
a controller operably connected to the first sensor and the second sensor and configured to generate a collision warning based on a braking distance of the host vehicle and a braking tendency of a driver of the host vehicle.

2. The apparatus of claim 1, wherein the controller is configured to calculate the braking distance of the host vehicle based on a mass of the host vehicle and a friction coefficient of a road surface.

3. The apparatus of claim 1, wherein the controller is configured to calculate the braking distance of the host vehicle in response to detection of a preceding vehicle located in front of the host vehicle.

4. The apparatus of claim 3, wherein the controller is configured to calculate the braking distance when a relative speed of the host vehicle with respect to the preceding vehicle is greater than or equal to a reference speed and the driver does not brake.

5. The apparatus of claim 4, wherein the controller is configured to control to brake the host vehicle when a distance between the host vehicle and the preceding vehicle is less than or equal to the braking distance.

6. The apparatus of claim 1, further comprising a memory configured to store an artificial neural network model generated by learning the braking tendency of the driver.

7. The apparatus of claim 6, wherein the artificial neural network model is generated by learning whether the driver brakes with consideration of the speed of the host vehicle, a distance between the host vehicle and a preceding vehicle located in front of the host vehicle, and a relative speed of the host vehicle with respect to the preceding vehicle.

8. The apparatus of claim 7, wherein the controller is configured to determine whether braking of the host vehicle needs to be performed based on an output of the artificial neural network model output by inputting the speed of the host vehicle, the distance between the host vehicle and the preceding vehicle, and the relative speed of the host vehicle with respect to the preceding vehicle into the artificial neural network model.

9. The apparatus of claim 8, wherein the artificial neural network model is configured to determine that the braking of the host vehicle needs to be performed based on learned data regarding that the driver braked at the speed of the host vehicle, the distance between the host vehicle and the preceding vehicle, and the relative speed of the host vehicle with respect to the preceding vehicle.

10. The apparatus of claim 8, wherein the artificial neural network model is configured to determine that the braking of the host vehicle does not need to be performed based on learned data regarding that the driver did not brake at the speed of the host vehicle, the distance between the host vehicle and the preceding vehicle, and the relative speed of the host vehicle with respect to the preceding vehicle.

11. The apparatus of claim 8, wherein the controller is configured to generate the collision warning in response to determination that the distance between the host vehicle and the preceding vehicle exceeds the braking distance and the braking of the host vehicle needs to be performed.

12. The apparatus of claim 6, wherein the artificial neural network model is configured to update learned data by learning the braking tendency of the driver at predetermined period of time.

13. The apparatus of claim 1, further comprising a memory configured to store a plurality of the artificial neural network models generated by learning braking tendencies of a plurality of drivers.

14. The apparatus of claim 13, wherein the controller is configured to select one of the plurality of artificial neural network models corresponding to one of the plurality of drivers, and determine whether braking of the host vehicle needs to be performed using the selected one of the plurality of the artificial neural network models.

15. The apparatus of claim 6, wherein the controller is operably connected to the first sensor and the second sensor through a CAN (Controller Area Network) of the host vehicle.

16. A method for collision avoidance of a host vehicle using a controller, the method comprising:
generating an artificial neural network model by learning a braking tendency of a driver of the host vehicle;
calculating a braking distance of the host vehicle when a relative speed of the host vehicle with respect to a preceding vehicle located in front of the host vehicle is greater than or equal to a reference speed and the driver does not brake;
determining whether braking of the host vehicle needs to be performed based on an output of the artificial neural network model output by inputting a speed of the host vehicle, a distance between the host vehicle and the preceding vehicle, and the relative speed of the host vehicle with respect to the preceding vehicle into the artificial neural network model; and
generating a collision warning in response to determination that the distance between the host vehicle and the preceding vehicle exceeds the braking distance and the braking of the host vehicle needs to be performed.

17. The method of claim 16, wherein the generating of the artificial neural network model comprises generating the artificial neural network model by learning whether the driver brakes with consideration of the speed of the host vehicle, the distance between the host vehicle and the preceding vehicle, and the relative speed of the host vehicle with respect to the preceding vehicle.

18. The method of claim 16, wherein the determining of whether the braking of the host vehicle needs to be performed comprises determining that the braking of the host vehicle needs to be performed based on learned data regarding that the driver braked at the speed of the vehicle, the distance between the vehicle and the preceding vehicle, and the relative speed of the host vehicle with respect to the preceding vehicle.

19. The method of claim 16, wherein the determining of whether the braking of the host vehicle needs to be performed comprises determining that the braking of the host vehicle does not need to be performed based on learned data regarding that the driver did not brake at the speed of the vehicle, the distance between the host vehicle and the preceding vehicle, and the relative speed of the host vehicle with respect to the preceding vehicle.

20. A non-transitory computer-readable storage medium configured to in which a program including instructions that when executed by one or more processors, cause the one or more processors to perform operations comprising:
generating an artificial neural network model by learning a braking tendency of a driver of the host vehicle;
calculating a braking distance of the host vehicle when a relative speed of the host vehicle with respect to a preceding vehicle located in front of the host vehicle is greater than or equal to a reference speed and the driver does not brake;
determining whether braking of the host vehicle needs to be performed based on an output of the artificial neural network model output by inputting a speed of the host vehicle, a distance between the host vehicle and the preceding vehicle, and the relative speed of the host vehicle with respect to the preceding vehicle into the artificial neural network model; and
generating a collision warning in response to determination that the distance between the host vehicle and the preceding vehicle exceeds the braking distance and the braking of the host vehicle needs to be performed.
